(19) United States
(12) Patent Application Publication
(10) Pub. No.: US 2014/0061910 A1
(43) Pub. Date: Mar. 6, 2014

(54) SEMICONDUCTOR DEVICE STRUCTURES AND METHODS FOR COPPER BOND PADS

(71) Applicants: CHU-CHUNG LEE, ROUND ROCK, TX (US); VIKAS R. SHETH, AUSTIN, TX (US)

(72) Inventors: CHU-CHUNG LEE, ROUND ROCK, TX (US); VIKAS R. SHETH, AUSTIN, TX (US)

(21) Appl. No.: 13/601,746

(22) Filed: Aug. 31, 2012

(51) Int. Cl. H01L 21/768; H01L 23/49

(52) U.S. Cl. 257/741; 438/612; 257/E23.024; 257/E21.576

(57) ABSTRACT

A method of making a semiconductor device can comprise forming a copper bond pad on an integrated circuit device; forming a first passivation layer on the integrated circuit device and the copper bond pad; forming a second passivation layer on the first passivation layer; forming a mask over the first and second passivation layers around the copper bond pad; etching the second passivation layer over the copper bond pad; and cleaning the first passivation layer over the copper bond pad. At least a portion of the first passivation layer remains over the copper bond pad after the etching the second passivation layer. A thickness of the first passivation layer over the copper bond pad is selected to protect the copper bond pad from oxidation and to allow wire bonding to the copper bond pad through the first passivation layer.

### BACKGROUND

The present invention relates generally to methods of forming semiconductor devices, and more particularly to semiconductor processes for semiconductor devices for copper bond pads.

### DESCRIPTION OF THE RELATED ART

In the integrated circuit (IC) industry, aluminum interconnects are now being replaced with copper-based inlaid interconnect structures. Copper interconnects are newer to the semiconductor industry and are very different from the more commonly used aluminum-based systems. For this reason, copper interconnects have uncovered new problems not before anticipated or addressed by integrated circuit manufacturing facilities.

Integrated circuit engineers are concerned with adverse chemical interactions that are associated with copper based materials and processing. Copper will adversely react with ambient air and oxidize in a manner that could reduce integrated circuit yield and/or adversely increase the resistance of the electrical connections.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 illustrates a side cross-sectional view of an embodiment of a semiconductor device during an intermediate stage of manufacture.

FIG. 2 illustrates a side cross-sectional view of the semiconductor device of FIG. 1 during a subsequent stage of manufacture.

FIG. 3 illustrates a side cross-sectional view of the semiconductor device of FIG. 2 during a subsequent stage of manufacture.

FIG. 4 illustrates a side cross-sectional view of the semiconductor device of FIG. 3 during a subsequent stage of manufacture.

FIG. 5 illustrates a side cross-sectional view of the semiconductor device of FIG. 4 during a subsequent stage of manufacture.

FIG. 6 illustrates a side cross-sectional view of another embodiment of a semiconductor device during an intermediate stage of manufacture.

FIG. 7 illustrates a side cross-sectional view of the semiconductor device of FIG. 6 during a subsequent stage of manufacture.

FIG. 8 illustrates a side cross-sectional view of the semiconductor device of FIG. 7 during a subsequent stage of manufacture.

FIG. 9 illustrates a side cross-sectional view of the semiconductor device of FIG. 8 during a subsequent stage of manufacture.

FIG. 10 illustrates a side cross-sectional view of the semiconductor device of FIG. 9 during a subsequent stage of manufacture.

### DETAILED DESCRIPTION

Embodiments of semiconductor devices and methods of manufacturing semiconductor devices with copper bond pads are disclosed that use existing fabrication processes to form a relatively thin protective layer on top of the copper bond pads. The thin protective layer can be cleaned with a Argon-Hydrogen plasma that enhanced the bondability of the protective layer while still protecting the copper bond pad from oxidation. An opening can be formed in the protective layer just prior to or concurrently with attaching wire bonds to the copper pads. The opening can be formed with a laser, by allowing the wire bonding equipment to punch a hole in the protective layer, or other suitable means. The resulting wire bond provides reliable connections even in high temperature environments due to the fact that the protective layer prevents oxide from forming on the copper bond pad. Further, the methods disclosed herein are adapted to use equipment and materials that are already commonly used in semiconductor manufacturing.

FIG. 1 illustrates a side cross-sectional view of an embodiment of a semiconductor device 100, such as an integrated circuit device, during an intermediate stage of manufacture. Device 100 includes two or more via interlayer dielectric layers (ILD) 104, 108 between respective metal ILDs 106, 110. Top metal layer 110 includes copper bond pad 102 that is an extension of a metal line (not shown) between bond pad 102 and one or more other components in Top metal layer 110 such as contacts 112, 114. Dielectric layer 108 includes conductive vias 118 between contact 112, 114 in metal ILD layer 110 and contact 116 in metal ILD layer 106. Dielectric layer 104 includes vias 118 to other components (not shown) in semiconductor device 100. Contacts 112, 114, 116 and vias 118 can be connected to active circuitry such as transistors, resistors, capacitors formed on a substrate (not shown) that is part of semiconductor device 100.

Bond pad 102 is large enough to support a ball or other type of bond which provides a mechanical, as well as electrical connection to the next level of interconnection. Typically the connection is made by bonding a gold or copper wire to the metal of the bond pad 102.

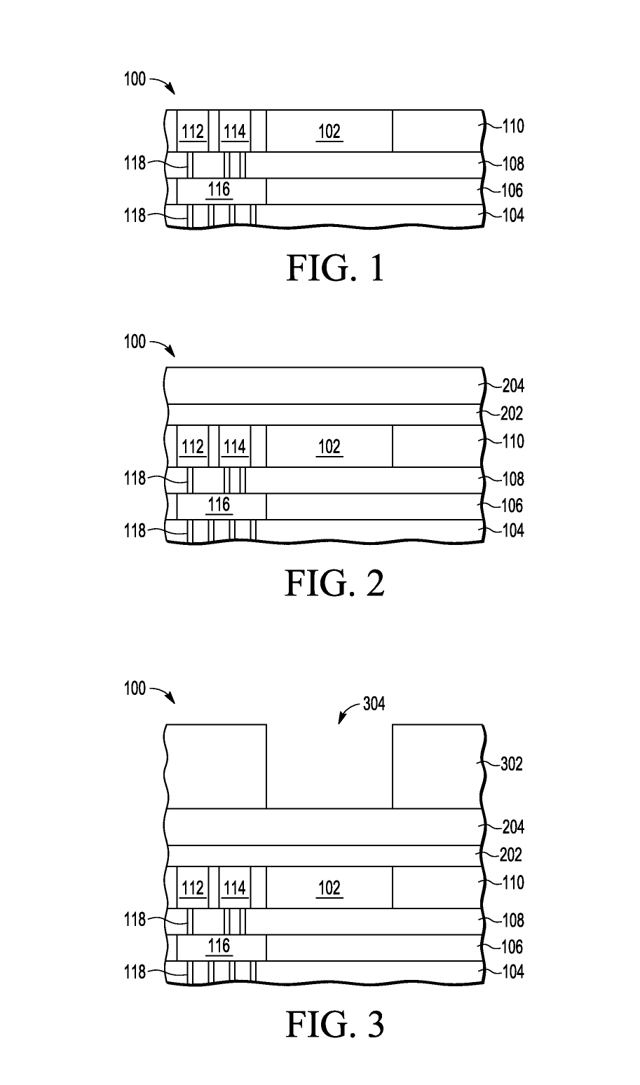

Referring to FIGS. 1 and 2, FIG. 2 illustrates a side cross-sectional view of the semiconductor device 100 of FIG. 1 during a subsequent stage of manufacture after first passivation layer 202 and second passivation layer 204 are formed over the top surface of metal layer 110, including bond pad 102.

First passivation layer 202 can be formed approximately 100 Angstroms thick (or other suitable thickness) of which a majority is removed over at least a portion of the bond pad 102 during subsequent processing. For example, if passivation layer 202 is approximately 100 Angstroms thick, the thickness of passivation layer 202 on top of bond pad 102 may be reduced to approximately 20 Angstroms (or other suitable thickness) during subsequent processing.

In some embodiments, passivation layer 202 can be formed of a layer of passivation material such as silicon dioxide, tetraethyl orthosilicate (TEOS), plasma enhanced nitride (PEN), any type of low k dielectric material, or over-pad metallurgy (OPM). The thickness of passivation layer 202 can range from 20 to 100 Angstroms in some embodiments, however, other suitable thicknesses can be used. Passivation layer 202 can be formed using a spin on, PECVD, or other suitable process.

Passivation layer 204 can be formed of a nitride or any other passivation material being used by a fabricator making the devices. The thickness of passivation layer 204 can be any suitable thickness.

FIG. 3 illustrates a side cross-sectional view of the semiconductor device 100 of FIG. 2 during a subsequent stage of manufacture in which layer of photoresist 302 has been deposited over passivation layer 204. A portion of photoresist layer 302 is removed to form a mask with an opening 304 in photoresist layer 302 over at least a portion of bond pad 102.

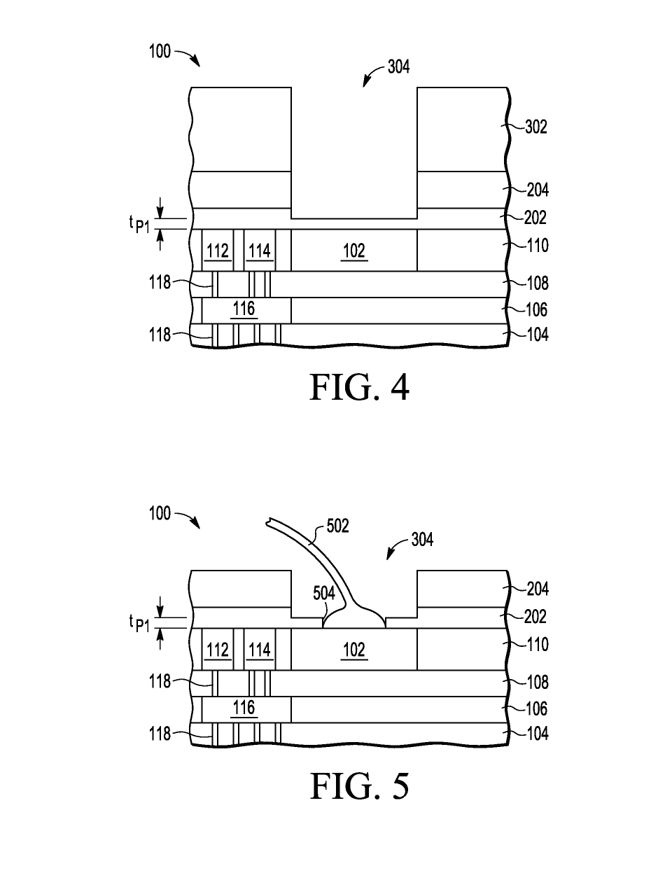

FIG. 4 illustrates a side cross-sectional view of the semiconductor device 100 of FIG. 3 during a subsequent stage of manufacture after passivation layer 204 has been completely removed within the side boundaries of opening 304. Additionally, the thickness (tₚ₁) of passivation layer 202 within the side boundaries of opening 304 has been reduced to a thickness that continues to protect bond pad 102 from oxidation while being thin enough to form a wire bond on pad 102 using conventional wire bonding equipment. In some embodiments, the thickness of the exposed portion of passivation layer 202 is approximately 20 Angstroms, however, other suitable thicknesses can be used.

In some embodiments, the exposed portion of passivation layer 202 can be cleaned using a combination of argon and hydrogen plasma before wire bonding. Using hydrogen (instead of oxygen) during the cleaning process is believed to change the properties of the exposed portion of passivation layer 202 so that an opening can be easily formed in passivation layer 202 to form a wire bond to bond pad 102.

FIG. 5 illustrates a side cross-sectional view of the semiconductor device 100 of FIG. 4 during a subsequent stage of manufacture after photoresist layer 302 is removed and wire bond 502 has been formed in an opening 504 of passivation layer 202. In some embodiments, passivation layer 202 can be weakened during the cleaning process to an extent that opening 504 can be formed using existing ultrasonic wire bonding equipment with a frequency of 140 kHz or less, or other suitable value. Alternatively, opening 504 for wire bond 502 can be formed by using a laser or other suitable device just before wire bonding.

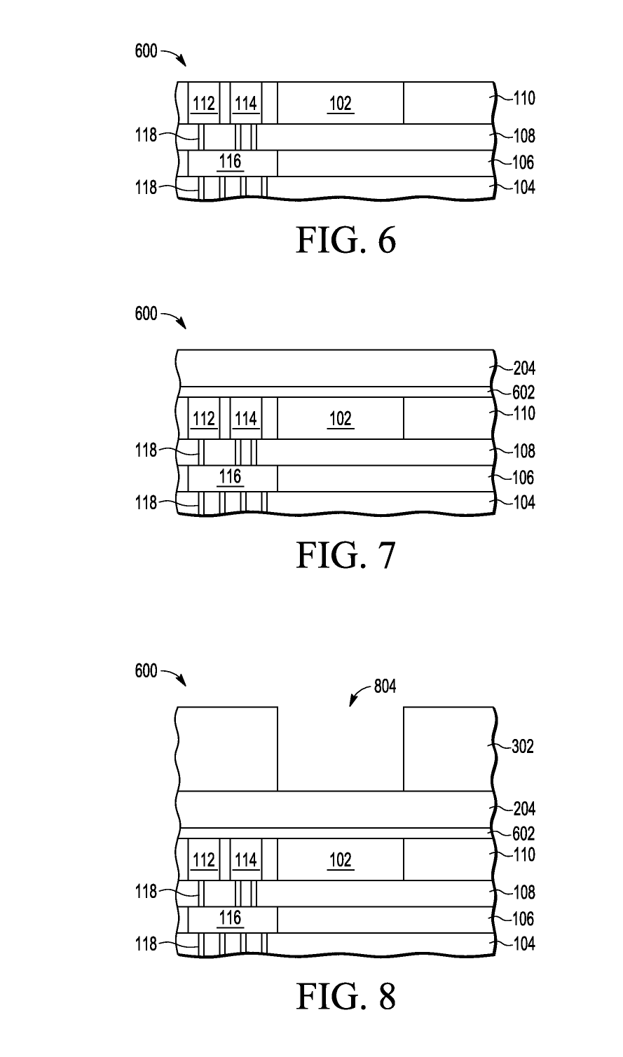

FIG. 6 illustrates a side cross-sectional view of another embodiment of a semiconductor device 600 during an intermediate stage of manufacture. Device 600 includes two or more Via ILD layers 104, 108 between respective metal ILD layers 106, 110. Top metal layer 110 includes copper bond pad 102 that is an extension of a metal line (not shown) between bond pad 102 and one or more other components in the top metal layer 110 such as contacts 112, 114. Dielectric layer 108 includes conductive vias 118 between contact 112, 114 in metal ILD layer 110 and contact 116 in metal ILD layer 106. Dielectric layer 104 includes vias 118 to other components (not shown) in semiconductor device 600. Contacts 112, 114, 116 and vias 118 can be connected to active circuitry such as transistors, resistors, capacitors formed on a substrate (not shown) that is part of semiconductor device 600.

Bond pad 102 is large enough to support a ball or other type of bond which provides a mechanical, as well as electrical connection to the next level of interconnection. Typically the connection is made by bonding a gold or copper wire to the metal of the bond pad 102.

Referring to FIGS. 6 and 7, FIG. 7 illustrates a side cross-sectional view of the semiconductor device 600 of FIG. 6 during a subsequent stage of manufacture after first passivation layer 602 and second passivation layer 204 are formed over the top surface of metal layer 110, including bond pad 102.

First passivation layer 602 is formed as a thin layer (e.g., approximately 20 Angstroms thick) or other suitable thickness of which none or very little is removed during subsequent processing. Additionally, the thickness (tₚ₁) of passivation layer 602 is chosen to protect bond pad 102 from oxidation while being thin enough to form a wire bond on pad 102 using conventional wire bonding equipment.

In some embodiments, passivation layer 602 can be formed of a layer of passivation material such as silicon dioxide, tetraethyl orthosilicate (TEOS), plasma enhanced nitride (PEN), any type of low k dielectric material, or over-pad metallurgy (OPM). Passivation layer 602 can be formed using a spin on, PECVD, or other suitable process. If the thickness of passivation layer 602 is approximately 20 Angstroms or less, the etch rate of passivation layer 602 can be different than the etch rate of passivation layer 204. The etch rates can be selected to allow an etchant that is selective of passivation layer 204 and non-selective of passivation layer 602 to be used to completely remove passivation layer 204 while not appreciably changing the thickness of passivation layer 602.

Passivation layer 204 can be formed of a nitride or any other passivation material being used by a fabricator making the devices. The thickness of passivation layer 204 can be any suitable thickness.

FIG. 8 illustrates a side cross-sectional view of the semiconductor device 600 of FIG. 7 during a subsequent stage of manufacture in which photoresist layer 302 has been deposited over passivation layer 204. A portion of photoresist layer 302 is removed to form a mask with an opening 804 in photoresist layer 302 over at least a portion of bond pad 102.

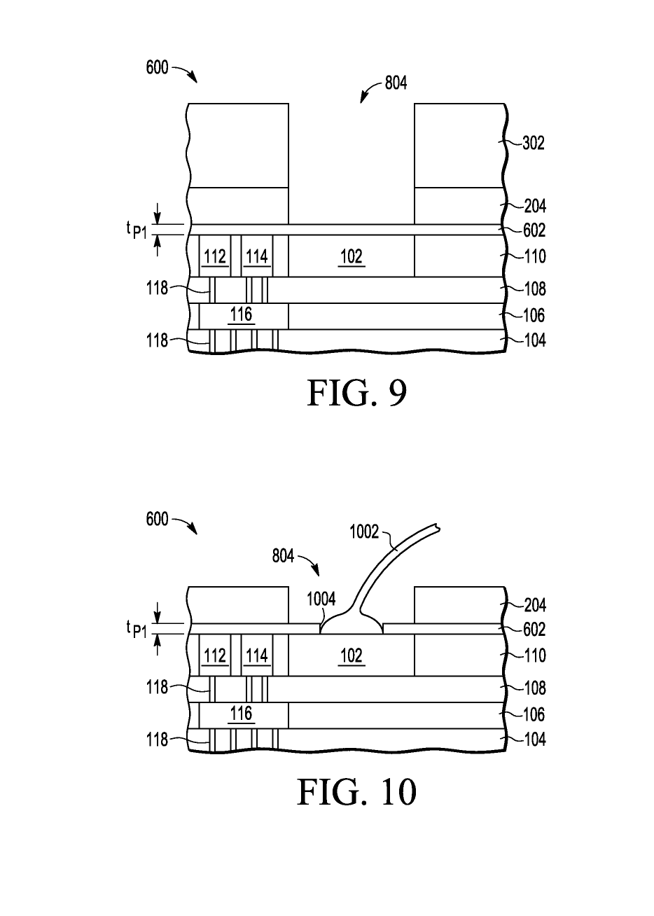

FIG. 9 illustrates a side cross-sectional view of the semiconductor device 600 of FIG. 8 during a subsequent stage of manufacture after passivation layer 204 has been removed within the side boundaries of opening 804. In some embodiments, the exposed portion of passivation layer 602 can be cleaned using a combination of argon and hydrogen plasma before wire bonding. Using hydrogen (instead of oxygen) during the cleaning process is believed to change the properties of the exposed portion of passivation layer 602 so that an opening can be easily formed in passivation layer 602 to form a wire bond to bond pad 102.

FIG. 10 illustrates a side cross-sectional view of the semiconductor device 600 of FIG. 9 during a subsequent stage of manufacture after photoresist layer 302 is removed and wire bond 1002 has been formed in an opening 1004 of passivation layer 602. In some embodiments, passivation layer 602 can be weakened during the cleaning process to an extent that opening 1004 can be formed using existing ultrasonic wire bonding equipment with a frequency of 140 kHz or less, or other suitable value. Alternatively, opening 1004 for wire bond 1002 can be formed by using a laser or other suitable device just before wire bonding.

The semiconductor substrate described herein can be any semiconductor material or combinations of materials, such as gallium arsenide, silicon germanium, silicon-on-insulator (SOI), silicon, monocrystalline silicon, the like, and combinations of the above.

By now it should be appreciated that semiconductor devices and methods have been provided that reduce manufacturing costs by eliminating the need for over pad metallurgy (OPM) on bond pads while using existing processes and equipment for semiconductor device manufacturing. The protective passivation layer 202 (FIG. 5), 602 (FIG. 10) is thick enough to prevent oxidation of copper bond pads, yet thin enough to allow wire bonds to be formed on the copper pad using existing wire bond equipment.

In some embodiments, a method of making a semiconductor device can comprise forming a copper bond pad on an integrated circuit device; forming a first passivation layer on the integrated circuit device and the copper bond pad; forming a second passivation layer on the first passivation layer; forming a mask over the first and second passivation layers around the copper bond pad; etching the second passivation layer over the copper bond pad; and cleaning the first passivation layer over the copper bond pad. At least a portion of the first passivation layer remains over the copper bond pad after the etching the second passivation layer. A thickness of the first passivation layer over the copper bond pad is selected to protect the copper bond pad from oxidation and to allow wire bonding to the copper bond pad through the first passivation layer.

In another aspect, the first passivation layer can be formed with a thickness of 30 Angstroms or less.

In another aspect, a hydrogen-rich plasma can be used in the cleaning the first passivation layer over the copper bond pad after the etching the second passivation layer.

In another aspect, the method can further comprise etching the first passivation layer over the copper bond pad to a thickness of 30 Angstroms or less.

In another aspect, the second passivation layer can include silicon oxy-nitride.

In another aspect, the first passivation layer can include one of a group consisting of: a plasma enhanced nitride (PEN), tetraethyl orthosilicate (TEOS), low K dielectric, porous material, silicon dioxide, dielectric resin, chemical vapor deposition (CVD) dielectric film, and protective metallic material.

In another aspect, the method of claim 1 can further comprise attaching a wire bond to the copper bond pad through the first passivation layer. A portion of the first passivation layer can be removed over the copper bond pad as part of the attaching the wire bond.

In another aspect, the first passivation layer can have a different etch rate than the second passivation layer.

In another aspect, the first passivation layer can be between 15 and 30 Angstroms thick.

In other embodiments, a method can comprise forming a copper bond pad on an integrated circuit device; forming a first passivation layer over the integrated circuit device and the bond pad; forming a second passivation layer over the first passivation layer; forming a mask over the first and second passivation layers around the copper bond pad; etching the second passivation layer over the bond pad; and exposing the first passivation layer over the bond pad to a cleaning substance. After the exposing, at least a portion of the first passivation layer can have a thickness that is between 15 and 30 Angstroms thick remains over the bond pad.

In another aspect, the exposing can include cleaning the first passivation layer over the copper bond pad with a hydrogen rich plasma after the etching the second passivation layer.

In another aspect, the exposing includes etching the first passivation layer over the copper bond pad using a hydrogen rich plasma.

In another aspect, the second passivation layer can include silicon oxy-nitride.

In another aspect, the first passivation layer can include one of a group consisting of: a plasma enhanced nitride (PEN), tetraethyl orthosilicate (TEOS), low K dielectric, porous material, silicon dioxide, dielectric resin, chemical vapor deposition (CVD) dielectric film, and protective metallic material.

In another aspect, the method can further comprise forming an opening in the first passivation layer over the copper bond pad prior to attaching a wire bond to the copper bond pad. The opening can formed during the attaching the wire bond to avoid oxidizing the copper bond pad.

In another aspect, the first passivation layer can have a different etch rate than the second passivation layer.

In still other embodiments, a semiconductor device can comprise a copper bond pad on an integrated circuit device; a first passivation layer over the integrated circuit device and the bond pad; and a second passivation layer formed after the first passivation layer. The second passivation layer is over the first passivation layer but not over the bond pad. A wire bond is attached to the copper bond pad through the first passivation layer.

In another aspect, the first passivation layer can be originally formed with a thickness between 15 and 30 Angstroms.

In another aspect, the first passivation layer can include one of a group consisting of: a plasma enhanced nitride (PEN), tetraethyl orthosilicate (TEOS), low K dielectric, porous material, silicon dioxide, dielectric resin, chemical vapor deposition (CVD) dielectric film, and protective metallic material.

In another aspect, the first passivation layer can be formed with a thickness greater than 20 Angstroms and etched to a thickness between 15 and 30 Angstroms.

Because the apparatus implementing the present disclosure is, for the most part, composed of electronic components and circuits known to those skilled in the art, circuit details will not be explained in any greater extent than that considered necessary as illustrated above, for the understanding and appreciation of the underlying concepts of the present disclosure and in order not to obfuscate or distract from the teachings of the present disclosure.

Although the disclosure is described herein with reference to specific embodiments, various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method of making a semiconductor device, comprising:
forming a copper bond pad on an integrated circuit device;
forming a first passivation layer on the integrated circuit device and the copper bond pad;
forming a second passivation layer on the first passivation layer;
forming a mask over the first and second passivation layers around the copper bond pad;
etching the second passivation layer over the copper bond pad; and
cleaning the first passivation layer over the copper bond pad,
wherein
at least a portion of the first passivation layer remains over the copper bond pad after the etching the second passivation layer, and
a thickness of the first passivation layer over the copper bond pad is selected to protect the copper bond pad from oxidation and to allow wire bonding to the copper bond pad through the first passivation layer.

2. The method of claim 1, wherein the first passivation layer is formed with a thickness of 30 Angstroms or less.

3. The method of claim 2 wherein a hydrogen-rich plasma is used in the cleaning the first passivation layer over the copper bond pad after the etching the second passivation layer.

4. The method of claim 1, further comprising:
etching the first passivation layer over the copper bond pad to a thickness of 30 Angstroms or less using the hydrogen rich plasma.

5. The method of claim 1, wherein the second passivation layer includes silicon oxy-nitride.

6. The method of claim 1, wherein the first passivation layer includes one of a group consisting of: a plasma enhanced nitride (PEN), tetraethyl orthosilicate (TEOS), low K dielectric, porous material, silicon dioxide, dielectric resin, chemical vapor deposition (CVD) dielectric film, and protective metallic material.

7. The method of claim 1, further comprising:
attaching a wire bond to the copper bond pad through the first passivation layer, wherein a portion of the first passivation layer is removed over the copper bond pad as part of the attaching the wire bond.

8. The method of claim 1, wherein the first passivation layer has a different etch rate than the second passivation layer.

9. The method of claim 1, wherein the first passivation layer is between 15 and 30 Angstroms thick.

10. A method comprising:
forming a copper bond pad on an integrated circuit device;
forming a first passivation layer over the integrated circuit device and the bond pad;
forming a second passivation layer over the first passivation layer;
forming a mask over the first and second passivation layers around the copper bond pad;
etching the second passivation layer over the bond pad; and
exposing the first passivation layer over the bond pad to a cleaning substance,
wherein
after the exposing, at least a portion of the first passivation layer having a thickness that is between 15 and 30 Angstroms thick remains over the bond pad.

11. The method of claim 10 wherein the exposing includes cleaning the first passivation layer over the copper bond pad with a hydrogen rich plasma after the etching the second passivation layer.

12. The method of claim 10, wherein:
the exposing includes etching the first passivation layer over the copper bond pad using a hydrogen rich plasma.

13. The method of claim 10, wherein the second passivation layer includes silicon oxy-nitride.

14. The method of claim 10, wherein the first passivation layer includes one of a group consisting of: a plasma enhanced nitride (PEN), tetraethyl orthosilicate (TEOS), low K dielectric, porous material, silicon dioxide, dielectric resin, chemical vapor deposition (CVD) dielectric film, and protective metallic material.

15. The method of claim 10, further comprising:
forming an opening in the first passivation layer over the copper bond pad prior to attaching a wire bond to the copper bond pad, wherein the opening is formed during the attaching the wire bond to avoid oxidizing the copper bond pad.

16. The method of claim 10, wherein the first passivation layer has a different etch rate than the second passivation layer.

17. A semiconductor device comprising:
a copper bond pad on an integrated circuit device;
a first passivation layer over the integrated circuit device and the bond pad;
a second passivation layer formed after the first passivation layer, wherein the second passivation layer is over the first passivation layer but not over the bond pad; and
a wire bond attached to the copper bond pad through the first passivation layer.

18. The device of claim 17, wherein the first passivation layer is originally formed with a thickness between 15 and 30 Angstroms.

19. The device of claim 17, wherein the first passivation layer includes one of a group consisting of: a plasma enhanced nitride (PEN), tetraethyl orthosilicate (TEOS), low K dielectric, porous material, silicon dioxide, dielectric resin, chemical vapor deposition (CVD) dielectric film, and protective metallic material.

20. The device of claim 17, wherein the first passivation layer is formed with a thickness greater than 20 Angstroms and etched to a thickness between 15 and 30 Angstroms.
